(19) United States
(12) Patent Application Publication
(10) Pub. No.: US 2026/0123049 A1
(43) Pub. Date: Apr. 30, 2026

(54) SEMICONDUCTOR-ON-INSULATOR DEVICE INCLUDING A BASE SUBSTRATE WITH FIELD CONTROL REGION

(71) Applicant: Infineon Technologies Austria AG, Villach (AT)

(72) Inventors: Felix Simon Winterer, Munchen (DE); Dirk Priefert, Moers (DE); Christian Schippel, Dresden (DE); Andrei Sidelnicov, Dresden (DE)

(21) Appl. No.: 19/324,369

(22) Filed: Sep. 10, 2025

(30) Foreign Application Priority Data
Sep. 26, 2024 (DE) 102024209352.1
Nov. 29, 2024 (DE) 102024135471.2

(51) Int. Cl. H10D 86/00; H03K 17/567

(52) U.S. Cl. CPC H10D 86/201; H03K 17/567; H03K 2217/0063; H03K 2217/0072

(57) ABSTRACT

A semiconductor-on-insulator device includes a base substrate with a background doping of a first conductivity type. A field control region of a complementary second conductivity type extends from a front surface into the base substrate. A net dopant concentration in the field control region decreases along a lateral direction parallel to the front surface at a lower rate than along a vertical direction orthogonal to the front surface. An insulator layer is formed on the front surface and a semiconductor layer is formed on the insulator layer. A semiconductor element in the semiconductor layer includes a first contact region over the field control region and a second contact region in the lateral direction of decreasing net dopant concentration in the field control region.

### TECHNICAL FIELD

The present disclosure relates to a semiconductor-on-insulator device having a base substrate in which a field control region is formed. Examples of the present disclosure relate to gate driver circuits with a high voltage part, a low voltage part, and high voltage semiconductor elements forming signal and/or power interfaces between the low voltage part and the high voltage part.

### BACKGROUND

High voltage semiconductor devices in CMOS technology (complementary metal oxide semiconductors) form an interface between standard CMOS devices with input voltages up to 5V on the one hand and industrial or consumer circuits operating with signal voltage levels above 30V on the other. Applications for such semiconductor devices exist in all kinds of power conversion and electrical drives up to the kV range, e.g., in power converters, robotics and the automotive industry. High voltage semiconductor devices typically include a low voltage part operating in a low voltage domain and a high voltage part operating in a high voltage domain. In the low voltage part, most of the signal processing is done at low operating voltage. The high voltage part operates at higher voltage level. The low voltage part and the high voltage part provide signal interfaces for power semiconductors using higher voltage levels and/or having higher current driving and sinking capability. The electric potentials of the different voltage domains can differ by several 100V up to some 1000V. An example of such a high voltage semiconductor device is a gate driver circuit. Gate driver circuits allow a microcontroller or DSP (digital signal processor) to efficiently turn on and off power semiconductor switches. Such semiconductor devices are typically silicon-on-insulator devices having high voltage semiconductor elements for exchanging electric signals between the CMOS circuits in the different voltage domains.

There is a constant need to improve signal transmission in semiconductor-on-insulator devices with high voltage semiconductor elements.

### SUMMARY

The present disclosure is related to a semiconductor-on-insulator device that includes a base substrate with a background doping of a first conductivity type. A field control region of a complementary second conductivity type extends from a front surface of the base substrate into the base substrate, wherein a net dopant concentration in the field control region decreases along a lateral direction parallel to the front surface at a lower rate than along a vertical direction orthogonal to the front surface. An insulator layer is formed on the front surface of the base substrate and a semiconductor layer is formed on the insulator layer. A semiconductor element formed in the semiconductor layer includes a first contact region formed over the field control region and a second contact region at a distance from the first contact region in the lateral direction of decreasing net dopant concentration in the field control region.

High voltage semiconductor-on-insulator devices typically include a high voltage device with a large potential transition region formed between first doping regions associated with a low voltage part and second doping regions associated with a high voltage part. The high voltage device includes the semiconductor elements for exchanging electric signals and/or electric power between the low voltage part and the high voltage part, wherein the semiconductor elements include low doped extension regions (drift regions) in the potential transition region. The field control region is formed in a portion of the base substrate directly below a first one of the contact regions of the semiconductor element at a first side of the potential transition region. The field control region includes a region of variation of lateral doping (VLD) that extends into the direction of the second contact region. The charges in the VLD region affect the charge carrier contribution in the drift portion and can be used to increase the doping of the drift region, for example to reducing the on-state resistance of a semiconductor element with a switching function. In the case of a high voltage device that includes two or more different semiconductor elements, the device characteristics of the semiconductor elements can be tuned independently of each other.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A and 1B include a schematic horizontal cross-sectional view and a schematic vertical cross-sectional view of a portion of a semiconductor-on-insulator device (SOI device) with a field control region having a net dopant concentration decreasing along a lateral direction at a lower rate than along a vertical direction (VLD region) in accordance with an embodiment.

FIGS. 2A and 2B include a schematic horizontal cross-sectional view and a schematic vertical cross-sectional view of a portion of an SOI device in accordance with an embodiment related to a high voltage device with two semiconductor elements sharing a portion of a central field control region in a back-to-back configuration.

FIGS. 3A to 3C include a schematic horizontal cross-sectional view and two schematic vertical cross-sectional views of a portion of an SOI device in accordance with an embodiment related to a stadium-shaped high voltage device with two semiconductor elements formed side-by-side and with VLD regions extending outwardly into the potential transition region.

FIGS. 4A to 4C include a schematic horizontal cross-sectional view and two schematic vertical cross-sectional views of a portion of an SOI device in accordance with an embodiment related to a stadium-shaped high voltage device with two semiconductor elements formed side-by-side and with VLD regions extending inwardly into the potential transition region.

FIGS. 5A and 5B include a schematic vertical cross-sectional view and a schematic horizontal cross-sectional view of a portion of an SOI device in accordance with an embodiment related to a high voltage device with a high voltage semiconductor diode.

FIGS. 6A and 6B include a schematic vertical cross-sectional view and a schematic horizontal cross-sectional view of a portion of an SOI device in accordance with an embodiment related to a high voltage device with a junction field effect transistor (JFET).

FIGS. 7A and 7B include a schematic vertical cross-sectional view and a schematic horizontal cross-sectional view of a portion of an SOI device in accordance with an embodiment related to a high voltage device with a high voltage bipolar junction transistor (BJT).

FIGS. 8A and 8B include a schematic vertical cross-sectional view and a schematic horizontal cross-sectional view of a portion of an SOI device in accordance with an embodiment related to a high voltage device with a high voltage insulated gate field effect transistor (IGFET).

FIG. 9 is a schematic block diagram of a gate driver circuit with BJTs and MOSFETs for passing differential data signals from a high-side part to a low-side part and from the low-side part to the high-side part in accordance with an embodiment.

### DETAILED DESCRIPTION

The terms “having”, “containing”, “including”, “including” and the like are open-ended, and the terms indicate the presence of certain structures, elements or features but do not preclude the presence of additional elements or features. The articles “a”, “an” and “the” include both the plural and singular, unless the context clearly indicates otherwise.

The terms “signal-connected” and “electrically coupled” include a permanent low-resistive ohmic connection between electrically connected elements, for example a direct contact between the concerned elements or a low-resistive connection via a metal and/or heavily doped semiconductor material, but do not preclude the presence of further passive and/or active elements in the signal path between the “signal-connected” or “electrically coupled” elements. For example, the further elements may include resistors, resistive conductor lines, capacitors and/or inductors, transistors, semiconductor diodes, Schottky diodes, transformers, opto-couplers and other.

The term “power semiconductor device” refers to semiconductor devices with a high voltage blocking capability of at least 30 V, for example 48 V, 100 V, 600 V, 1.6 kV, 3.3 kV or more and with a nominal on-state current or forward current of at least 200 mA, for example 1 A, 10 A or more.

An ohmic contact describes a non-rectifying electrical junction between two conductors, e.g., between a semiconductor material and a metal. The ohmic contact has a linear or approximately linear current-voltage (I-V) curve in the first and third quadrant of the I-V diagram as with Ohm's law.

Ranges given for physical dimensions include the boundary values. For example, a range for a parameter y from a to b reads as a s y s b. The same holds for ranges with one boundary value like “at most” and “at least”.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

Two adjoining doping regions in a semiconductor layer form a semiconductor junction. Two adjoining doping regions of the same conductivity type and with different dopant concentrations form a unipolar junction, e.g., an n/n+ or p/p+ junction along a boundary surface between the two doping regions. At the unipolar junction a dopant concentration profile orthogonal to the unipolar junction may show a step or a turning point, at which the dopant concentration profile changes from being concave to convex, or vice versa. Two adjoining doping regions of complementary conductivities form a pn junction.

The Figures illustrate relative doping concentrations by indicating “−” or “+” next to the doping type “n” or “p”. For example, “n-” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

The examples described herein provide a semiconductor-on-insulator device. The semiconductor-on-insulator device includes a base substrate, an insulator layer, and a semiconductor layer. The base substrate has a background doping of a first conductivity type, wherein a field control region of a complementary second conductivity type extends from a front surface into the base substrate, and wherein a net dopant concentration in the field control region decreases along a lateral direction parallel to the front surface at a lower rate than along a vertical direction orthogonal to the front surface. The insulator layer is formed on the front surface of the base substrate. The semiconductor layer is formed on the insulator layer, wherein a semiconductor element formed in the semiconductor layer includes a first contact region formed over the field control region and a second contact region formed at a lateral distance from the field control region.

The base substrate may include a single crystalline silicon layer having a weak background doping of the first conductivity type. The field control region contains the background doping and a complementary doping resulting from implanting dopants of the complementary doping type and annealing the implanted dopants. A net doping is given by the difference between the doping resulting from the implanted dopants and the background doping. In at least a portion of the field control region, the net dopant concentration decreases in the lateral direction from a maximum net doping concentration on one side to a minimum net doping concentration on the opposite side of the field control region. The minimum net doping concentration may be less than 15% of the maximum net dopant concentration, e.g. zero net doping (equilibrium doping). In addition to having one or more portions with decreasing dopant concentration, the field control region may also include one or more portions with constant net dopant concentration.

The lateral decrease in net dopant concentration may be monotonic, e.g., step-wise or strictly monotonic. For example, the net dopant concentration may decrease linearly, according to a square root function, or according to a logarithmic function. The average rate at which the net dopant concentration decreases in the lateral direction may be at most 50%, e.g., at most 20% or at most 10% of the rate at which the net dopant concentration decreases in the vertical direction. The lateral diffusion profile can be obtained by locally modifying the implanted dose of dopants of the second conductivity type using an implantation mask with laterally changing ion permeability per unit area. For example, the area occupancy of the front surface of the base substrate by the implantation mask and/or the vertical extension of the implantation mask increases in the lateral direction.

The first conductivity type can be n conductivity and the second conductivity type p conductivity. Alternatively, the first conductivity type is p conductivity and the second conductivity type n conductivity.

The insulator layer is formed directly on the front surface and separates the base substrate and the semiconductor layer from each other. The insulator layer may be a homogenous layer or may be a layer stack including two or more sub-layers that differ from each other in the material composition and/or density.

The semiconductor layer may have a uniform background doping of the first or second conductivity type. A vertical extension of the first contact region and the second contact region may be equal to the vertical extension of the semiconductor layer. The first contact region and the second contact region may have the same conductivity type or may have different conductivity types. The dopant concentrations in the first contact region and the second contact region are sufficiently high to form low-resistive ohmic contacts with suitable metals, e.g., aluminum, tantalum, titanium, tungsten, copper, silver, or heavily doped polycrystalline silicon. The semiconductor layer, the insulator layer and the base substrate form an SOI (silicon-on-insulator) die.

The semiconductor element may be a high voltage semiconductor device or a semiconductor switching device, for example a bipolar junction transistor (BJT), a junction field effect transistor (JFET) or an insulated gate field effect transistor (IGFET), for example an MOSFET (metal oxide semiconductor field effect transistor (MOSFET) in the broader sense including FETs with polysilicon gate electrodes.

The semiconductor element forms part of a high voltage device with a central region, a peripheral region and a potential transition region separating the peripheral region from the central region. The first contact region is formed in the central region and the second contact region may be formed in the peripheral region. The semiconductor element includes an extension region or drift region in the potential transition region.

Vertical projections of the first contact region and the field control region into the plane of the front surface overlap each other. Vertical projections of the second contact region and a portion of the field control region with laterally decreasing net dopant concentration into the plane of the front surface may overlap each other or may be laterally separated from each other. The smooth lateral transition of the field control region may improve some of the device characteristics of the semiconductor element formed in the semiconductor layer without adverse effects on the voltage blocking capability.

According to an embodiment, the field control region may include a doping transition region. In the doping transition region, the net dopant concentration decreases at an average first rate in the lateral direction and at an average second rate in the vertical direction, wherein the average second rate is at least twice the average first rate.

The shallower decrease in the lateral direction can be achieved by implanting the dopants through an implantation mask having openings and tuning the local implant dose by varying the local ratio between the cross-sectional area of the openings and the cross-sectional area of the mask material in a unit area from a higher value to lower value.

A lateral length d0 of the doping transition region along a lateral direction with maximum doping gradient may be at twice, e.g., at least five times or at least 10 times a maximum vertical extension v0 of the doping transition region. For example, the net dopant concentration decreases from 85% of the maximum net dopant concentration to 15% of the maximum net dopant concentration over a distance of 65 μm in the lateral direction and over a distance of about 3 μm in the vertical direction.]

Vertical projections of the second contact region and the doping transition region into the plane of the front surface may overlap each other or may be laterally separated from each other.

According to an embodiment, the field control region may further include a constant doping region of constant net dopant concentration in direct lateral contact with the doping transition region.

The side of the maximum dopant concentration in the doping transition region is oriented to the constant doping region. The dopant concentration in the constant doping region and the maximum doping concentration in the doping transition region may be equal.

The constant doping region may be a lateral continuous region with the maximum dopant concentration of the doping transition region and without gaps. Alternatively, the constant doping region may laterally embed gaps having a different conductivity type and/or different dopant concentrations. Lateral transitions of the net dopant concentration between the constant doping region and the embedded gaps are significantly steeper than the lateral variation of doping in the doping transition region.

According to an embodiment, the second contact region may be formed at a lateral distance from the constant doping region.

The second contact region may be formed over the doping transition region, wherein vertical projections of the second contact region and the doping transition region in the plane of the front surface overlap each other. Alternatively, the second contact region may be formed at a lateral distance from the field control region, wherein vertical projections of the second contact region and the field control region in the plane of the front surface do not overlap each other.

According to an embodiment, the doping transition region may include sections on opposite sides of the constant doping region, wherein the net dopant concentration in the sections of the doping transition region decreases in a direction away from the constant doping region.

The constant doping region may be rectangular, rectangular with rounded corners, circular or stadium-shaped with a rectangular portion and two tapering portions at opposite sides of the rectangular portion. The tapering portions may be semicircular portions, wherein the diameter of each semicircular portion can be equal to the corresponding side length of the rectangular portion.

According to an embodiment, the doping transition region may laterally surround the constant doping region, wherein the net dopant concentration in the doping transition region decreases outwards in a radial direction.

The constant doping region may be circular, rectangular with rounded corners, or stadium-shaped with a rectangular portion and two tapering portions at opposite sides of the rectangular portion. The tapering portions may be semicircular portions, wherein the diameter of each semicircular portion can be equal to the corresponding side length of the rectangular portion.

The outer edge of the constant doping region may be the outer edge of a first voltage region that may include the low side part of a gate driver circuit.

For a doping transition region forming a circular ring, the radial direction is directed from the center point of the circular ring. For the semicircular portions of a stadium-shaped doping transition region, the radial direction is directed from the center point from the respective semicircle. For the rectangular portion of a stadium-shaped doping transition region, the radial direction is orthogonal to a symmetry line connecting the two center points of the semicircular portions.

According to an embodiment, the doping transition region may laterally surround a second voltage region and the net dopant concentration in the doping transition region decreases inwards in a radial direction.

In a semiconductor-on-insulator device with constant doping region, the constant doping region forms a ring at the outer edge of the ring-shaped doping transition region. The second voltage region may include the high side part of a gate driver circuit.

The doping transition region may be constant and without steps in a tangential direction orthogonal to the radial direction.

According to an embodiment, the doping transition region includes at least a first sector and a second sector, wherein the first sector and the second sector have different net dopant gradients in the radial direction.

Each sector extends in the radial direction as defined above. When the doping transition region forms a ring including straight sections, each sector can be formed in a straight section. The net dopant gradients may differ as regards the maximum dopant concentration, the rate of the lateral decrease in net dopant concentration, and/or the type of gradient linear, square root, logarithmic, where different semiconductor elements are formed in laterally separated portions of the semiconductor layer, the net dopant gradient in each sector can be adapted to the type of semiconductor element formed over the same sector in the semiconductor layer.

According to an embodiment, a channel stopper region of the first conductivity type may be formed in the base substrate in direct lateral contact with the field control region.

The channel stopper region may laterally extend from the field control region to a neighboring doped region of the second conductivity type, e.g., a field region in the second voltage region. A maximum vertical extension v2 of the channel stopper region may be smaller than the maximum vertical extension v0 of the field control region, e.g., at most 50%, 20%, or 10% of the maximum vertical extension v0 of the field control region 250. A net dopant concentration in the channel stopper region is lower than in the field control region 250. A net dopant concentration in the channel stopper region may be lower than in the maximum net dopant concentration in the field control region. The channel stopper region may suppress formation of a parasitic transistor channel along the front surface between the field control region and the next doped region of the second conductivity type. The presence of the channel stopper region may also increase the process window for the background doping of the base substrate.

Forming the channel stopper region may include a shallow ion implantation through the front surface of the base substrate and annealing the base substrate. The ion implantation may be an unmasked implantation (blanket implantation) that decreases the net dopant concentration in a vertical section of the field control region directly adjoining the front surface.

According to an embodiment, a voltage reduction structure may be formed in the semiconductor layer between the first contact region and the second contact region.

The voltage reduction structure may be designed to withstand a blocking voltage applied between the first contact region and the second contact region, wherein the blocking voltage may be at least 60V, e.g., at least 100V or at least 600V. The voltage reduction structure may include a lightly doped lateral drift zone of a conductivity type of the second contact region, wherein the drift zone may be uniformly doped or may have a lateral doping gradient, and wherein the drift zone may be combined with a more heavily doped buffer region between the drift zone and the second contact region.

According to an embodiment, the voltage reduction structure may include first compensation regions of the first conductivity type and second compensation regions of the second conductivity type, wherein the first and second compensation regions alternate along a tangential direction orthogonal to shortest connection lines between the first contact region and the second contact region.

The first compensation regions and the second compensation regions form a compensation structure (superjunction structure), wherein the doping concentrations and the extensions along a lateral tangential direction orthogonal to the radial direction, the number charges of dopants in the first compensation regions and the number of dopants in the second compensation regions are selected so that in the blocking state the compensation structure is completely depleted from mobile charge carriers. Charges in the first compensation regions and the second compensation regions largely cancel each other out in the presence of an electric field to which the field control region contributes.

Compared to field rings, the process of forming the doping transition region with the variation of lateral doping can be more stable and/or the charge compensation effect is less sensitive to process variations for the doping transition region than for field rings. For n-channel IGFETs, the dopant concentration in n conductive compensation regions can be increased to reduce the on-state resistance RDSon. For p-channel JFETs, the dopant concentration in p conductive compensation regions can be increased to reduce the on-state resistance RDSon. In addition, different semiconductor elements in the same high voltage device may be provided with doping transition regions having different lateral lengths d0.

According to an embodiment, the first contact region and the second contact region have a different conductivity type.

The voltage reduction structure may extend from the first contact region to the second contact region. The voltage reduction structure may include a lightly doped drift zone extending from the first contact region to the second contact region. Alternatively, the voltage reduction structure may include a buffer region between the lightly doped drift zone and the second contact region. Alternatively, the voltage reduction structure may include a compensation structure with the first compensation regions and the second contact region forming unipolar junctions. The second compensation regions and the first contact region may form unipolar junctions or may be separated by a lightly doped region of the conductivity type of the first contact region.

For example, the first contact region is p-conductive and the second contact region is n-conductive. The semiconductor element is a semiconductor diode with the first contact region forming the anode and the second contact region forming the cathode.

According to an embodiment, the first contact region and the second contact region have a same conductivity type.

The voltage reduction structure may be in direct contact with a first one of the first contact region and the second contact region and may be separated from the second one of the first contact region and the second contact region. The voltage reduction structure may include a lightly doped drift zone of the conductivity type of the first and second contact regions and form a unipolar junction with one of the first contact region and the second contact region. Alternatively, the voltage reduction structure may include a buffer region of the conductivity type of the drift zone between the lightly doped drift zone and a first one of the first contact region and the second contact region. Alternatively, the voltage reduction structure may include a compensation structure with the first compensation regions and a first one of the first contact region and the second contact region forming unipolar junctions.

For example, the first and second contact regions are p-conductive. The semiconductor element may be a pnp BJT bipolar junction transistor, a p channel JFET junction field effect transistor, or a p channel IGFET insulated gate field effect transistor, e.g., a MOSFET.

According to an embodiment, a voltage reduction structure may be formed in the semiconductor layer between the first contact region and the second contact region, wherein gate regions of a conductivity type complementary to the conductivity type of the first and second contact regions are formed in the semiconductor layer between the voltage reduction structure and a first one of the first and second contact regions. The gate regions are laterally separated along a tangential direction orthogonal to shortest connection lines between the first and second contact regions.

The gate regions are laterally separated by channel regions of the complementary conductivity type. If the voltage reduction structure includes first compensation regions and second compensation regions, the first compensation regions may have the same lateral center-to-center distance as the gate regions. Each gate region may form a unipolar junction with a compensation region of the same conductivity type. Each channel region may form a unipolar junction with a compensation region of the same conductivity type.

For example, the semiconductor element may be a p channel JFET with the first and second contact regions being p conductive and the gate regions being n conductive. The gate regions can be formed as lateral extensions of the first compensation regions and the channel regions can be formed as lateral extensions of the second compensation regions.

According to another embodiment with a voltage reduction structure being formed in the semiconductor layer between the first contact region and the second contact region, a base/body region of a conductivity type complementary to the conductivity type of the first and second contact regions may be formed in the semiconductor layer between the voltage reduction structure and a first one of the first and second contact regions.

The base/body region may laterally separate the voltage reduction structure from the first one of the first and second contact regions. Alternatively, a further doped region of the conductivity type of the adjacent contact region may be formed between the voltage reduction structure and the first one of the first and second contact regions, wherein a net dopant dose of the further doped region is smaller than in the first one of the first and second contact regions.

According to an embodiment, the semiconductor-on-insulator device may include a third contact structure, wherein the third contact structure and the base/body region form an ohmic contact.

The base/body region forms the base region of a BJT. For example, the semiconductor element may be a pnp BJT with the first and second contact regions being p conductive and the base region being n conductive, wherein the base region may be formed between the voltage reduction structure and the second contact region.

According to another embodiment, the semiconductor-on-insulator device may include a gate electrode and gate dielectric separating the base/body region and the gate electrode from each other.

The base/body region forms the body region of an IGFET, e.g., a MOSFET. For example, the semiconductor element may be an n channel MOSFET with the first and second contact regions being n-conductive and the base/body region being p-conductive, wherein the base/body region is formed between the first contact region and the voltage reduction structure.

According to an embodiment, the semiconductor-on-insulator device may include a passivation layer, wherein the passivation layer may be formed on the semiconductor layer and wherein the passivation layer may include a silicon nitride.

The silicon nitride may be a silicon nitride with a higher silicon content as a stoichiometric silicon nitride Si₃N₄(SiSiN). The SiSiN passivation layer is sufficiently resistive to avoid charge accumulation in the layers over the semiconductor element. The SiSiN layer is robust against deterioration originating from incorporating humidity and can replace a metal structure, e.g., a field plate structure shielding the semiconductor layer against charges accumulated in the passivation layer.

According to an embodiment, the semiconductor-on-insulator device may include a low side circuit and a high side circuit. The low side circuit may be configured to generate a low side data signal and output a first gate drive signal between a first gate output and a first reference potential VSS. The high side circuit may be configured to generate a high side data signal and output a second gate drive signal between a second gate output and a second reference potential VS. The semiconductor element may be configured to transfer a voltage and/or pass the low side data signal from the low side circuit to the high side circuit and/or pass the high side data signal from the high side circuit to the low side circuit. The semiconductor-on-insulator device may be an integrated gate driver device.

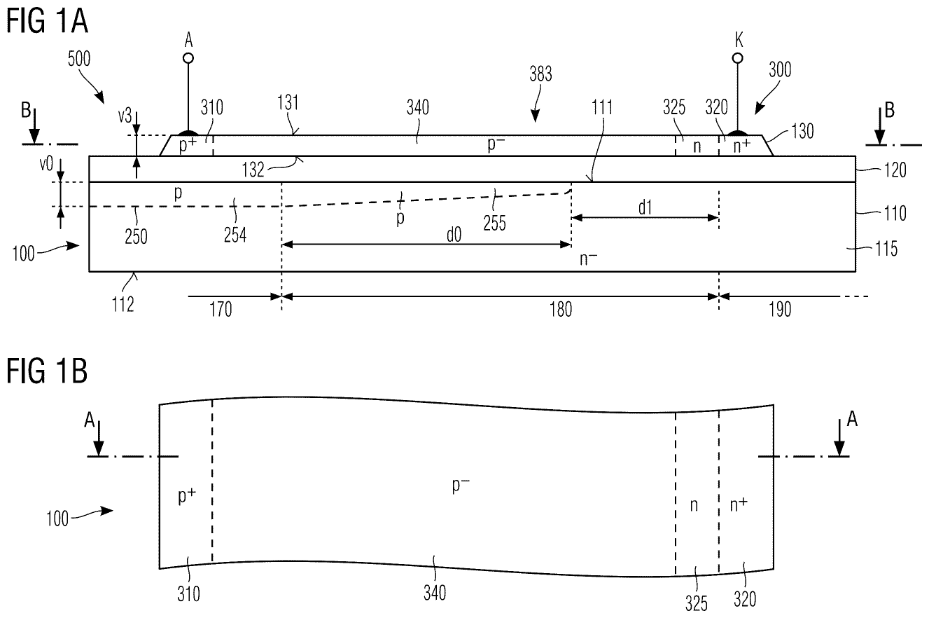

FIG. 1A and FIG. 1B show a portion of a semiconductor-on-insulator device 500 with a high voltage semiconductor diode 383. Semiconducting regions of the high voltage semiconductor diode 383 are formed in a semiconductor layer 130. The semiconductor layer 130 has a first surface 131 at a front side and a second surface 132 opposite to the front side. The first surface 131 and the second surface 132 are formed in two parallel horizontal planes. A normal to the horizontal planes defines a vertical direction. The semiconductor layer 130 includes a single-crystalline silicon layer of uniform vertical extension (thickness) between the first surface 131 and the second surface 132. A vertical extension v3 of the semiconductor layer 130 may be in a range from 50 nm to 1 μm, e.g., in a range from 100 nm to 150 nm.

The semiconductor layer 130 has a homogeneous background doping. In the illustrated example, the semiconductor layer 130 has a weak p-type (p-) background doping. Doped regions 310, 320, 325 in the semiconductor layer 130 contain the background doping and dopants implanted by ion beam implantation through the first surface 131 and activated in a heat treatment.

An insulator layer 120 separates the second surface 132 of the semiconductor layer 130 from a front surface 111 of a base substrate 110. The semiconductor layer 130 and the insulator layer 120 are in direct contact with each other and form a horizontal interface. A vertical extension of the insulator layer 120 may be in a range from 200 nm to 3 μm, e.g., in a range from 400 nm to 600 nm. The insulator layer 120 may be a homogeneous layer or may be a layer stack that includes at least two layers of different composition and/or structure. For example, the insulator layer 120 may include or be a semiconductor oxide layer, e.g., a silicon oxide layer.

The base substrate 110 includes a single crystalline silicon layer having a weak background doping with n-conductivity. The semiconductor layer 130, the insulator layer 120 and the base substrate 110 form an SOI (silicon-on-insulator) die 100.

A p conductive field control region 250 extends from the front surface 111 into the base substrate 110. The field control region 250 includes a constant doping region 254, which has a constant net dopant concentration, and a doping transition region 255. The doping transition region 255 shows a variation of lateral doping, wherein the net dopant concentration decreases at a significantly lower rate in the lateral direction than in the vertical direction. In the embodiment shown, the net dopant concentration decreases linearly with increasing lateral distance from the constant doping region 254 over a lateral length d0. A vertical extension of the doping transition region 255 decreases linearly with increasing lateral distance from the constant doping region 254. A background doping region 115 having the background doping separates the field control region 250 from a back surface 112 of the base substrate 110.

The constant doping region 254 and the doping transition region 255 are in direct contact with each other and the maximum net dopant concentration in the doping transition region 255 is the same as in the constant doping region 254.

The semiconductor layer 130 includes a first contact region 310 and a second contact region 320 in a lateral distance from the first contact region 310. The first contact region 310 is formed over the constant dopant region 254, wherein vertical projections of the first contact region 310 and the constant dopant region 254 into the plane of the front surface 111 of the base substrate 110 overlap each other. The second contact region 320 is formed at a first lateral distance d1 from an outer lateral edge of the field control region 250. A vertical extension of the first contact region 310 and the second contact region 320 may be equal to the vertical extension v3 of the semiconductor layer 130.

The first contact region 310 is p conductive and forms an anode contact region electrically connected with an anode terminal A. The second contact region 320 is n conductive and forms a cathode contact region electrically connected with a cathode terminal K. A voltage reduction region 350 between the first contact region 310 and the second contact region 320 is designed for a high voltage blocking capability of at least 60V.

In the illustrated example, the voltage reduction region 350 includes a lightly p doped drift zone in direct contact with the first contact region 310. An n conductive buffer region 325 laterally separates the drift zone and the second contact region 320 from each other.

The first contact region 310 and the constant dopant region 254 are formed in a first voltage region 170 of the semiconductor-on-insulator device 500. The second contact region 320 is formed in a second voltage region 190 of the semiconductor-on-insulator device 500. A transition region 180 laterally separating the first voltage region 170 and the second voltage region 190 may extend from an edge of the constant dopant region 254 oriented to the second voltage region 190 to an edge of the second contact region 320 oriented to the first voltage region 170.

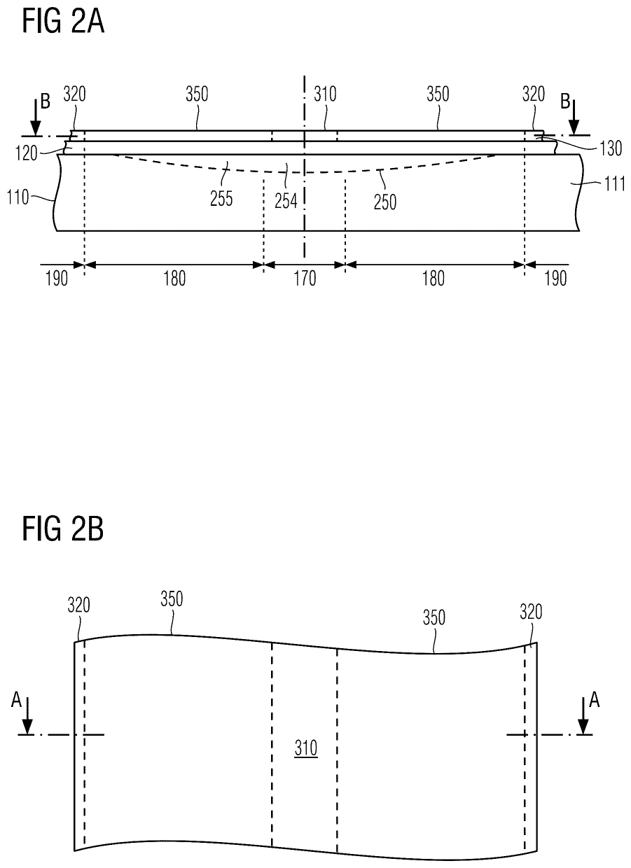

In FIGS. 2A and 2B, the first voltage region 170 includes a rectangular portion. Two portions of the transition region 180 on opposite sides of the first voltage region 170 separate the first voltage region 170 from two portions of the second voltage region 190 formed on opposite sides of the first voltage region 170. In the base substrate 110, the field control region 250 includes a rectangular section of a constant doping region 254 in the first voltage region 170 and two sections of a doping transition region 255 on opposite sides of the first voltage region 170 in the transition region 180. In the semiconductor layer 130, a first contact region 310 is formed in the first voltage region 170 and two separated second contact regions 320 are formed on opposite sides of the first contact region 310 in the second voltage region 190.

In a case where the two second contact regions 320 are electrically separated, two different semiconductor elements are formed on opposite sides of the first voltage region 170. In a case where the two second contact regions 320 are directly electrically connected through a low-impedance path, two parts of the same semiconductor element are formed on opposite sides of the first voltage region 170.

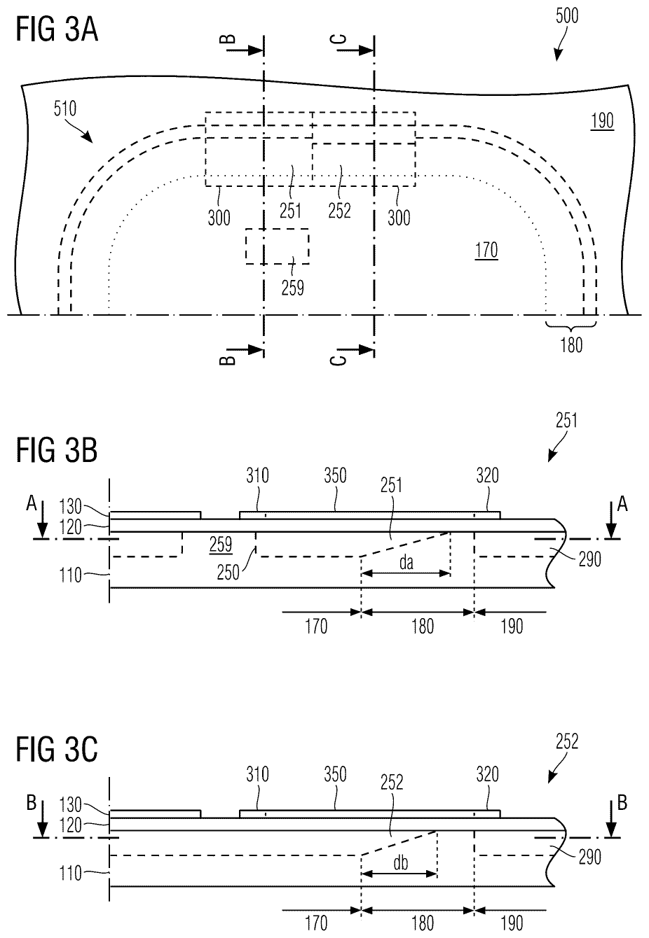

FIG. 3A, FIG. 3B and FIG. 3C show a portion of a semiconductor-on-insulator device 500 with a high voltage device 510 that includes two semiconductor elements 300 formed side-by-side.

The high voltage device includes a stadium-shaped first voltage region 170 having one rectangular section and two tapering sections on opposite sides of the rectangular section. Each tapering section includes two quarter-cycle sections and a further rectangular section connecting the two quarter-cycle sections. The transition region 180 laterally surrounds the first voltage region 170 with a uniform width. The first voltage region 170 and the transition region 180 are formed symmetrically with respect to two orthogonal lateral axes of symmetry. A second voltage region 190 connects to the outside edge of the transition region 180 and surrounds the transition region 180.

In the base substrate 110, a field control region 250 is formed that includes a constant doping region 254 in the first voltage region 170 and a doping transition region 255 in the transition region 180. The doping transition region 255 laterally surrounds the constant doping region 254, wherein in the doping transition region 255 the net dopant concentration decreases with increasing distance to the constant doping region 254 in a radial direction. The constant doping region 254 laterally surrounds a gap 259 having the background doping of the base substrate 110. A p conductive field region 290 is formed in the base substrate 110 in the second voltage region 190.

A lateral transition of the net dopant concentration between the constant doping region 254 and the embedded gap 259 and a lateral transition of the net dopant concentration along the lateral edge of the field region 290 are significantly steeper than the lateral variation of doping in the doping transition region 255.

The doping transition region 255 includes a first sector 251 and a second sector 252, wherein the first sector 251 and the second sector 252 have different net dopant gradients in a radial direction orthogonal to one of the lateral axes of symmetry. The first sector 251 and the second sector 252 are formed in a straight section of the transition region 180. The net dopant gradient in the first sector 251 is shallower than the net dopant gradient in the second sector 252. A first lateral length da of the first sector 251 is greater than a second lateral length db of the second sector 252. The first sector 251 is part of a first semiconductor element 300 and the second sector 252 is part of a second semiconductor element 300, wherein the net dopant gradient of the doping transition region 255 in the first and second sectors 251, 252 are independent from each other and can be individually adapted to the type of semiconductor element 300 formed over the respective sector 251, 252.

In the illustrated example, the doping transition region 255 is also formed along the tapering portions of the constant doping region 254. In another example (not illustrated), the doping transition region 255 is absent along the tapering portions of the constant doping region 254.

The semiconductor-on-insulator device 500 may be a gate driver circuit, with a high voltage part formed in the first voltage region and the low voltage part formed in the second voltage region. The low voltage part includes logic and analog circuits using a first supply voltage reference potential and the high voltage part includes logic and analog circuits using a second supply voltage reference potential, wherein the first supply voltage reference potential and the second supply voltage reference potential diverge from each other by more than 50V. A first one of the semiconductor elements may be an n-channel MOSFET for transmitting electric signals from the low voltage part to the high voltage part and a p-channel JFET for transmitting electric signals from the high voltage part to the low voltage part.

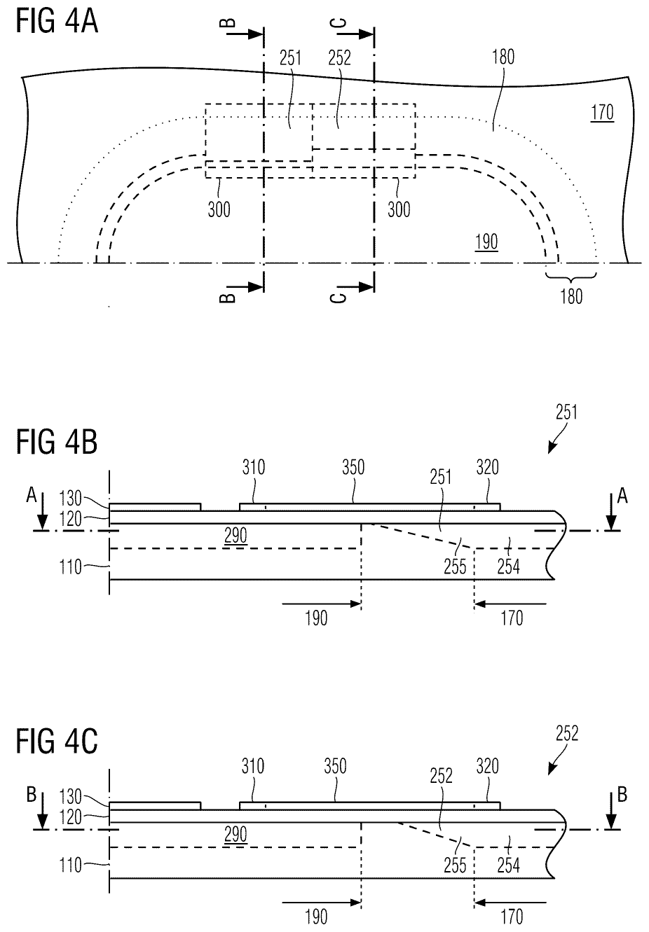

FIG. 4A, FIG. 4B, and FIG. 4C show a semiconductor-on-insulator device with a stadium-shaped second voltage region 190 that includes one rectangular section and two semicircular sections on opposite sides of the rectangular section. A ring-shaped transition region 180 of uniform width laterally surrounds the second voltage region 190. The second voltage region 190 and the transition region 180 are formed symmetrically with respect to two orthogonal lateral axes of symmetry. A first voltage region 170 connects to the outside edge of the transition region 180 and surrounds the transition region 180.

In the base substrate 110, a field control region 250 is formed that includes a constant doping region 254 in the first voltage region 170 and a doping transition region 255 in the transition region 180. The doping transition region 255 extends from the constant doping region 254 inwardly into the transition region 180, wherein in the doping transition region 255 the net dopant concentration decreases with increasing distance to the constant doping region 254 in a radial direction. A p conductive field region 290 is formed in the base substrate 110 in the second voltage region 190.

The doping transition region 255 includes a first sector 251 and a second sector 252. In the first sector 251 the doping transition region 255 has a shallower gradient than in the second sector 252. The first sector 251 and the second sector 252 are formed in a straight section of the transition region 180. In the illustrated example, the doping transition region 255 is also formed along the bowed portions of the constant doping region 254. In another example (not illustrated), the doping transition region 255 is absent along the bowed portions of the constant doping region 254.

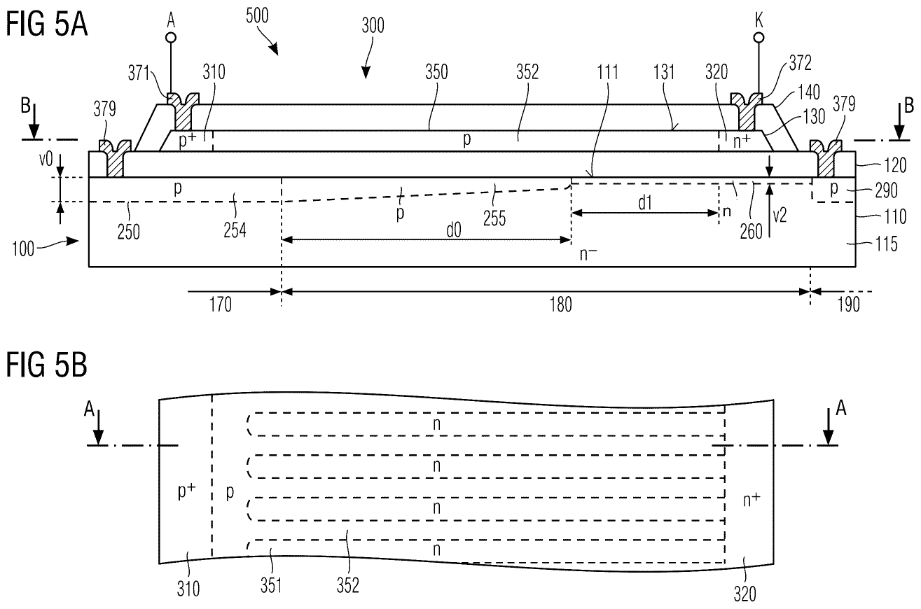

In FIGS. 5A and 5B, a p-conductive field control region 250 with a constant dopant region 254 formed in a first voltage region 170 extends from a front surface 111 into a base substrate 110 with a weak background doping of n-type conductivity. In a second voltage region 190 surrounding the first voltage region 170, a p-conductive field region 290 extends from the front surface 111 into the base substrate 110. In a transition region 180 separating the first voltage region 170 and the second voltage region 190 from each other, a n-conductive channel stopper region 260 extends from the front surface 111 into the base substrate 110. In the radial direction, the channel stopper region 260 extends from a doping transition region 255 of the field control region 250 to the p-conductive field region 290 in the second voltage region 190. A maximum vertical extension v2 of the channel stopper region 260 is smaller than the maximum vertical extension v0 of the field control region 250.

An insulator layer 120 is formed on the front surface 111 of the base substrate 110. Substrate contact structures 379 extend through openings in the insulator layer 120 to the base substrate 110 and form ohmic contacts with the constant doping region 254 and the field region 290.

A portion of a semiconductor layer 130 is formed on the insulator layer 120. A first contact region 310 is formed in the semiconductor layer 130 in the first voltage region 170 and above the constant doping region 254. A second contact region 320 is formed in the semiconductor layer 130 in an outer section of the transition region 180 oriented to the second voltage region 190 and above the channel stopper region 260.

A passivation layer 140 is formed on a first surface 131 of the semiconductor layer 130. The first contact region 310 and a first contact structure 371 extending through an opening in the passivation layer 140 form an ohmic contact. The second contact region 320 and a second contact structure 372 extending through an opening in the passivation layer 140 form an ohmic contact. Between the first contact region 310 and the second contact region 320, a compensation structure is formed in the semiconductor layer 130.

The compensation structure includes stripe-shaped first compensation regions 351 and stripe-shaped second compensation regions 352. The first compensation regions 351 and second compensation regions 352 have complementary types of conductivity type and alternate in a tangential direction orthogonal to the radial direction. In the illustrated example, the first compensation regions 351 are n-conductive and the second compensation regions 352 are p-conductive. Lateral longitudinal axes of the first compensation regions 351 and the second compensation regions 352 are parallel to each other and the radial direction. The first compensation regions 351 and the second contact regions 320 form semiconductor junctions.

The semiconductor element 300 formed in the semiconductor layer 130 is a high voltage semiconductor diode with a p-conductive first contact region 310 and an n-conductive second contact region 320. The first contact structure 371 is electrically connected to an anode terminal A and the second contact structure 372 is electrically connected to cathode terminal K.

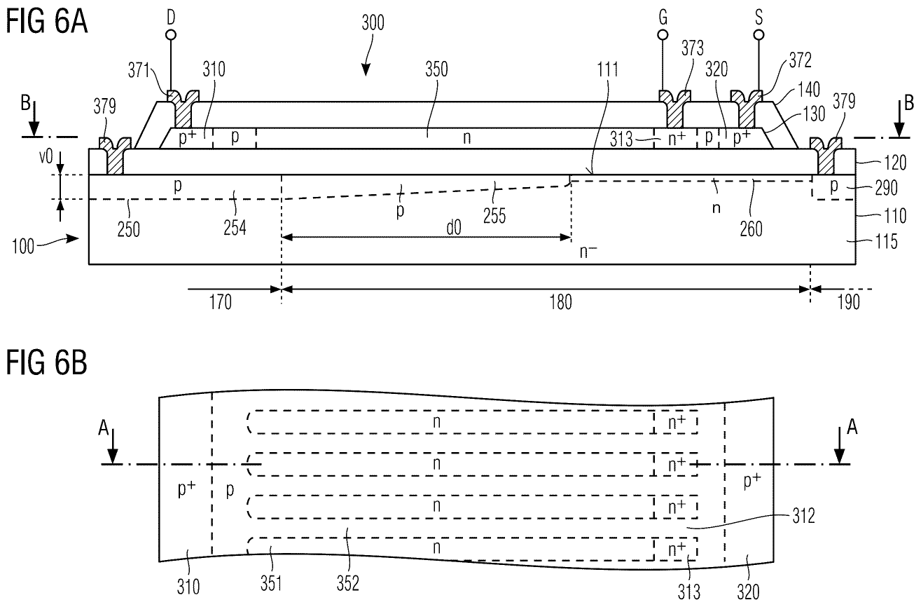

In FIGS. 6A and 6B, the semiconductor element 300 is a p-channel JFET with a p-conductive first contact region 310, a p-conductive second contact region 320, and heavily doped gate regions 313 in direct contact with the n-conductive first compensation regions 351. P-conducive lateral extensions of the second compensation regions 352 form channel regions 312 that laterally separate the gate regions 313 from each other. The gate regions 313 and third contact structures 373 extending through openings in the passivation layer 140 form ohmic contacts. The first contact structure 371 is electrically connected to a drain terminal D, the second contact structure 372 is electrically connected to source terminal S, and the third contact structure 373 is electrically connected to a gate terminal G.

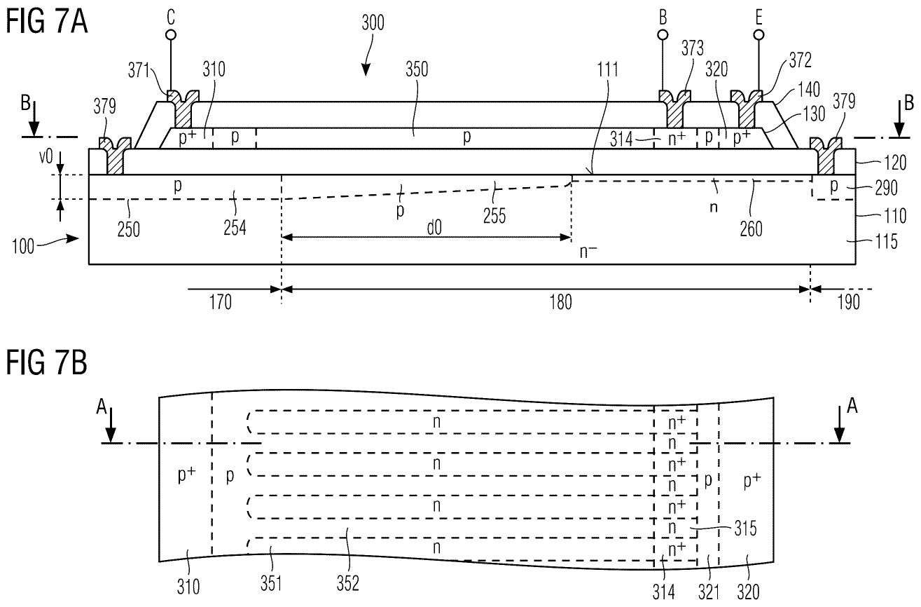

In FIGS. 7A and 7B, the semiconductor element 300 is a pnp BJT with a p-conductive first contact region 310, a p-conductive second contact region 320, and heavily doped base contact regions 314 in direct contact with the n-conductive first compensation regions 351. N-conducive base regions 315 connect the base contact regions 314 along the tangential direction orthogonal to the radial direction. The base contact regions 314 and third contact structures 373 extending through openings in the passivation layer 140 form ohmic contacts. The first contact structure 371 is electrically connected to a collector terminal C, the second contact structure 372 is electrically connected to an emitter terminal E, and the third contact structure 373 is electrically connected to a base terminal B.

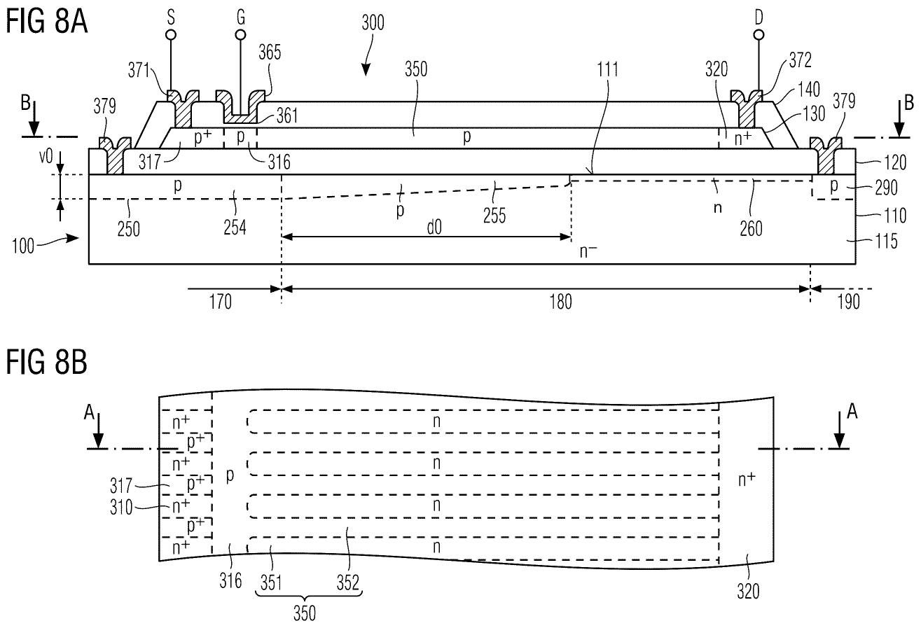

In FIGS. 8A and 8B, the semiconductor element 300 is an n-channel MOSFET with n-conductive first contact regions 310, a p-conductive second contact region 320, heavily doped body contact regions 317 alternating with the first contact regions 317 along the tangential direction, and a p-conductive body region 316 laterally separating the first contact regions 310 and the body contact regions 317 on a first side from the compensation structure on the opposite side. A gate dielectric 361 is formed directly on the semiconductor layer 130 above the body region 316. A gate electrode 365 is formed directly on the gate dielectric 361.

The first contact regions 310 and the body contact regions 317 form ohmic contacts with first contact structures 371 extending through openings in the passivation layer 140 to the semiconductor layer 130. The first contact structures 371 are electrically connected to a source terminal S, the second contact structure 372 is electrically connected to a drain terminal D.

The gate electrode 365 is electrically connected to a gate terminal G.

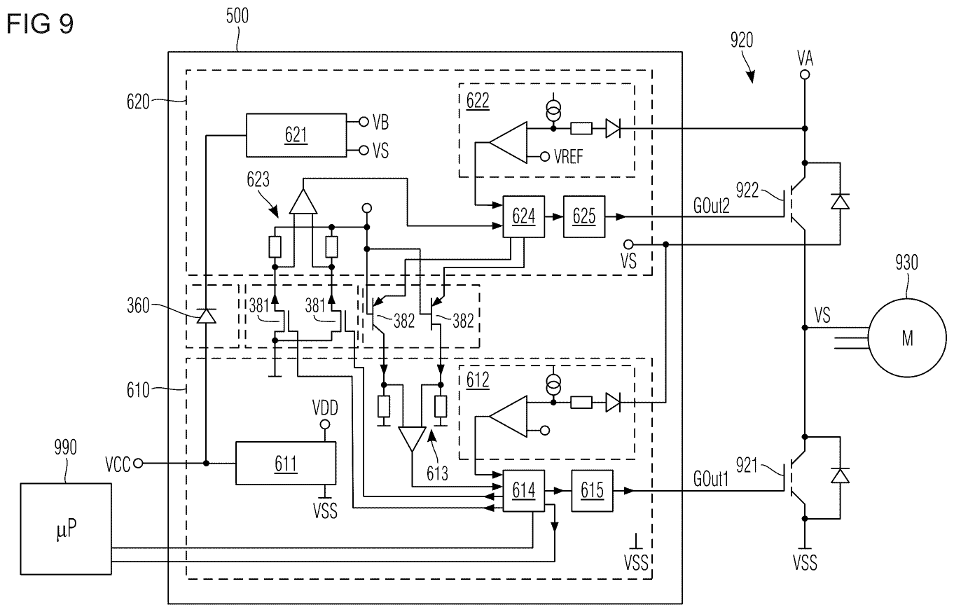

FIG. 9 shows a semiconductor-on-insulator device 500 configured as gate driver circuit. The gate driver circuit includes a high side part 620 configured to drive a gate of a high side switch 922 of a half bridge and a low side part 610 configured to drive a gate of a low side switch 921 of the half bridge. The semiconductor-on-insulator device 500 includes a high side power supply circuit 621 to obtain a positive power supply voltage VB for the high side part 620 (high side supply potential VB), wherein a bootstrap diode 360 charges a bootstrap capacitor from an external supply voltage VCC. The positive power supply voltage VB for the high side part 620 is referenced to a high side reference potential VS, which corresponds to the potential of the switching node of a half bridge 920.

A high side desaturation detection circuit 622 is connected to the supply potential VA of the half bridge 920, detects a desaturation of the high side switch 922 of the half bridge 920, and outputs a high side desaturation signal indicating whether a desaturation condition exists. A high side receiver circuit 623 receives a differential gate control signal from two field effect transistors, e.g., n channel MOSFETs 381 as described above and outputs a single-ended high side gate control signal. A logic circuit 624 in the high side part 620 receives the high side desaturation signal and the high side gate control signal. The logic circuit 624 in the high side part 620 outputs a second gate drive signal GOut2 in response to the high side gate control signal provided that the high side desaturation signal does not indicate a desaturation condition. A high side driver stage 625 may drive the second gate drive signal GOut2.

The logic circuit 624 in the high side part further outputs a differential high side data signal. Two pnp BJTs 382 as described above transmit the differential high side data signal from the high side part 620 to a low side receiver circuit 613 in the low side part 610.

The low side part 610 of the gate driver circuit includes a low side power supply circuit 611 to obtain a positive power supply voltage VDD for the low side part 610. The positive power supply voltage VDD for the low side part 610 is referenced to the first reference potential VSS.

A low side desaturation detection circuit 612 is connected to the output node of the half bridge 920, detects a desaturation of the low side switch 921, and outputs a low side desaturation signal indicating whether a desaturation condition exists. A low side receiver circuit 613 receives a differential low side data signal from the pnp BJTs 382 and outputs a single-ended low side data signal. A logic circuit 614 in the low side part 610 receives the low side data signal, the low side desaturation signal, and a low side gate control signal from an external source like a processor 990. The logic circuit 614 in the low side part 610 outputs a first gate drive signal GOut1 in response to the low side gate control signal provided that none of the low side desaturation signal and the low side data signal indicates a desaturation condition. A low side driver stage 615 drives the first gate drive signal GOut1.

The logic circuit 614 in the low side part 610 further outputs a differential gate control signal. The two n channel MOSFETs 381 transmit the differential gate control signal from the low side part 610 to the high side part 620. An inductive load 930 is electrically connected between the switching nodes of two half bridges 920.

The n channel MOSFETs 381 and pnp BJTs 382 having any of the configurations of the present embodiments improve the signal transfer between the low side part 610 and the high side part 620, reduce the leakage current between high side part 620 and low side part 610, can be formed more compact and can reduce switching time and therefore improve the performance of the half bridge 920 by allowing higher switching frequencies.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the semiconductor-on-insulator devices including its preferred embodiments as outlined in the present document may be used stand-alone or in combination with the other semiconductor-on-insulator devices disclosed in this document. In addition, the features outlined in the context of a semiconductor-on-insulator devices are also applicable to a corresponding method, and vice versa. Furthermore, all aspects of the semiconductor-on-insulator devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A semiconductor-on-insulator device, comprising:
a base substrate with a background doping of a first conductivity type, wherein a field control region of a complementary second conductivity type extends from a front surface into the base substrate, and wherein a net dopant concentration in the field control region decreases along a lateral direction parallel to the front surface at a lower rate than along a vertical direction orthogonal to the front surface;
an insulator layer on the front surface; and
a semiconductor layer on the insulator layer, wherein a semiconductor element in the semiconductor layer comprises a first contact region over the field control region and a second contact region in the lateral direction of decreasing net dopant concentration in the field control region.

2. The semiconductor-on-insulator device of claim 1,
wherein the field control region comprises a doping transition region,
wherein in the doping transition region, the net dopant concentration decreases at an average first rate in the lateral direction and at an average second rate in the vertical direction, and
wherein the average second rate is at least twice the average first rate.

3. The semiconductor-on-insulator device of claim 2,
wherein the field control region further comprises a constant doping region of constant net dopant concentration in direct lateral contact with the doping transition region.

4. The semiconductor-on-insulator device of claim 3,
wherein the second contact region is at a lateral distance from the constant doping region.

5. The semiconductor-on-insulator device of claim 4,
wherein the doping transition region comprises sections on opposite sides of the constant doping region, and
wherein the net dopant concentration in the sections of the doping transition region decreases in a direction away from the constant doping region.

6. The semiconductor-on-insulator device of claim 2,
wherein the doping transition region laterally surrounds a first voltage region, and
wherein the net dopant concentration in the doping transition region decreases outwards in a radial direction.

7. The semiconductor-on-insulator device of claim 2,
wherein the doping transition region laterally surrounds a second voltage region, and
wherein the net dopant concentration in the doping transition region decreases inwards in a radial direction.

8. The semiconductor-on-insulator device of claim 2,
wherein the doping transition region laterally surrounds a first voltage region and laterally surrounds a second voltage region,
wherein the net dopant concentration in the doping transition region decreases inwards or outwards in a radial direction,
wherein the doping transition region further comprises at least a first sector and a second sector, and
wherein the first sector and the second sector have different net dopant gradients in the radial direction.

9. The semiconductor-on-insulator device of claim 1, further comprising:
a channel stopper region of the first conductivity type in the base substrate and in direct lateral contact with the field control region.

10. The semiconductor-on-insulator device of claim 1, further comprising:
a voltage reduction structure in the semiconductor layer between the first contact region and the second contact region.

11. The semiconductor-on-insulator device of claim 10,
wherein the voltage reduction structure comprises a plurality of first compensation regions of the first conductivity type and a plurality of second compensation regions of the second conductivity type, and
wherein the first and second compensation regions alternate along a tangential direction orthogonal to shortest connection lines between the first contact region and the second contact region.

12. The semiconductor-on-insulator device of claim 1,
wherein the first contact region and the second contact region have a same conductivity type.

13. The semiconductor-on-insulator device of claim 12, further comprising:
a voltage reduction structure in the semiconductor layer between the first contact region and the second contact region,
wherein a plurality of gate regions of a conductivity type complementary to a conductivity type of the first and second contact regions is formed in the semiconductor layer between the voltage reduction structure and a first one of the first and second contact regions, and
wherein the gate regions are laterally separated along a tangential direction orthogonal to shortest connection lines between the first and second contact regions.

14. The semiconductor-on-insulator device of claim 1,
wherein the first contact region and the second contact region have a different conductivity type.

15. The semiconductor-on-insulator device of claim 14, further comprising:
a voltage reduction structure in the semiconductor layer between the first contact region and the second contact region,
wherein a base/body region of a conductivity type complementary to a conductivity type of the first and second contact regions is formed in the semiconductor layer between the voltage reduction structure and a first one of the first and second contact regions.

16. The semiconductor-on-insulator device of claim 15, further comprising:
a third contact structure,
wherein the third contact structure and the base/body region form an ohmic contact.

17. The semiconductor-on-insulator device of claim 15, further comprising:
a gate electrode; and
a gate dielectric separating the base/body region and the gate electrode from each other.

18. The semiconductor-on-insulator device of claim 1, further comprising:
a passivation layer on semiconductor layer,
wherein the passivation layer comprises silicon and silicon nitride.

19. The semiconductor-on-insulator device of claim 1, further comprising:
a low side circuit configured to generate a low side data signal and output a first gate drive signal between a first gate output and a first reference potential; and
a high side circuit configured to generate a high side data signal and output a second gate drive signal between a second gate output and a second reference potential,
wherein the semiconductor element is configured to transfer a voltage and/or pass the low side data signal from the low side circuit to the high side circuit, and/or pass the high side data signal from the high side circuit to the low side circuit.
